(19) United States
(12) Patent Application Publication
(10) Pub. No.: US 2025/0246704 A1
(43) Pub. Date: Jul. 31, 2025

(54) BATTERY OPTIMAL DYNAMIC TEMPERATURE CONTROL

(71) Applicant: Caterpillar Inc., Peoria, IL (US)

(72) Inventor: Karl P. Schneider, Decatur, IL (US)

(73) Assignee: Caterpillar Inc., Peoria, IL (US)

(21) Appl. No.: 18/428,457

(22) Filed: Jan. 31, 2024

(51) Int. Cl. H01M 10/613; G01R 31/367; G01R 31/374; G01R 31/382; G01R 31/392; G01R 31/396; H01M 10/625; H01M 10/633; H01M 10/635; H01M 10/6551

(52) U.S. Cl. CPC H01M 10/613; G01R 31/367; G01R 31/374; G01R 31/382; G01R 31/392; G01R 31/396; H01M 10/633; H01M 10/635; H01M 10/6551; H01M 10/625; H01M 2220/20

(57) ABSTRACT

A system for cooling a battery of an electric machine can include a controller, a battery system coupled to the controller, and a cooling system coupled to the controller and configured to cool the battery system, wherein, the controller is configured to dynamically adjust a battery cooling system temperature set point or cooling demand based on a condition of the battery system and an application environment.

### TECHNICAL FIELD

The present disclosure generally relates to cooling system control for an electric battery vehicle.

### BACKGROUND

In response to fuel efficiency concerns and desired performance characteristics, an emphasis has been placed on using electrical power to operate various components associated with a vehicle. Battery powered machines include one or more energy storage devices (e.g., batteries) to send and receive electrical energy.

Battery electric machines are unique from most other applications, such as automotive, as the battery lifecycle is defined by cyclic aging of the battery, whereas most other applications degrade from calendar aging. The distinction is that the use and care of the battery in a battery electric machine is important for lifecycle duration and subsequently cost, of which battery is the largest component.

The key factors in battery cyclic degradation are state of charge, current, depth of discharge, and battery temperature. In an electric machine environment, the current is largely determined by the application needs and battery size, and the state of charge is generally optimized based on the depth of discharge for a particular application as to avoid unnecessary downtime for charging. This leaves temperature, which the machine does have a control over, but can be very costly in terms of weight, monetary (lifecycle cost), and power (efficiency, battery throughput life).

Therefore, it is important for the machine to use the battery cooling wisely, as to optimize the benefit for the given cost.

CN1114122558 discusses a battery pack cooling system with active and passive cooling and one of the active cooling flow path, the passive cooling flow path and the cold storage flow path is controlled to be conducted to work according to the vehicle state, the battery pack cell temperature, the environment temperature and the outlet cooling liquid temperature of the radiator.

### SUMMARY

In an example, according to this disclosure, a system for cooling a battery of an electric machine can include a controller, a battery system coupled to the controller, and a cooling system coupled to the controller and configured to cool the battery system, wherein, the controller is configured to dynamically adjust a battery cooling system temperature set point or cooling demand based on a condition of the battery system and an application environment.

In one example, a system for cooling a battery of an electric machine can include a controller, a battery system coupled to the controller, and a cooling system coupled to the controller and configured to cool the battery system, wherein the controller is configured to dynamically adjust a battery cooling set point based on a minimum temperature set point of one of a battery lifecycle temperature set point, an opportunistic temperature set point, and a degradation target temperature set point.

In one example, a system for cooling a battery of an electric machine can include a controller, a battery system coupled to the controller, and a cooling system coupled to the controller and configured to cool the battery system, wherein the cooling system includes an active cooling system and a passive cooling system, wherein the controller is configured to use the passive cooling system when a cooling demand is below a passive cooling capacity due to cold ambient conditions and/or low application load factor, and to use the active system when the cooling demand is greater than the passive cooling capacity and the active cooling capacity is greater than the passive cooling capacity.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is schematic view of a cooling system for an electric machine, in accordance with this disclosure.

FIG. 2 is a schematic view of a control system for opportunistic overcooling, in accordance with one example.

FIG. 3 is a schematic view of a control system for lifecycle overcooling, in accordance with one example.

FIG. 4 is a schematic view of a control system for cooling based on degradation, in accordance with one example.

FIG. 5A is a schematic view of a control system for cooling based on TCO degradation, in accordance with one example.

FIG. 5B is a continuation of the schematic of FIG. 5A.

FIG. 6 is a schematic view of a combined cooling control system, in accordance with one example.

FIG. 7 shows a graph of battery cooling capacity, in accordance with this disclosure.

FIG. 8 shows a graph depicting lifecycle temperature sensitivity, in accordance with this disclosure.

FIG. 9 shows a blown-up portion of the graph of FIG. 8.

FIG. 10 shows a graph depicting overcooling lifecycle value, in accordance with this disclosure.

### DETAILED DESCRIPTION

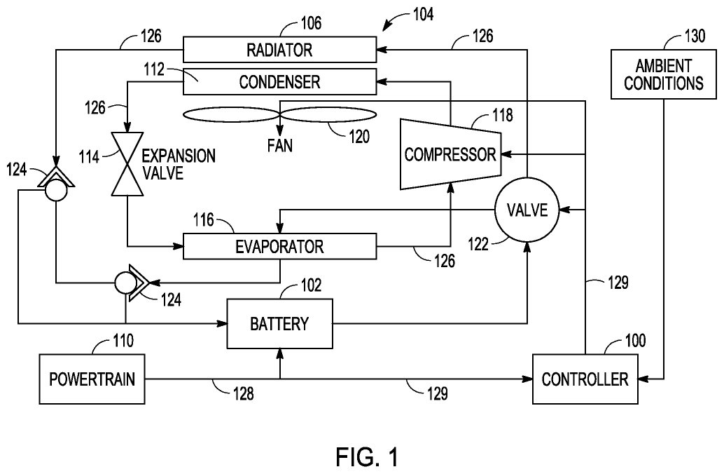

FIG. 1 is schematic view of a battery cooling system for an electric machine, in accordance with this disclosure. In general, the system can include a controller 100, a battery system 102 coupled to the controller 100, and a cooling system 104 coupled to the controller 100 and configured to cool the battery system 102.

The controller 100 can receive ambient conditions 130 from outside sensors. The ambient conditions can include ambient temperature and pressure, for example. A valve 122 can be used by the controller 100 to change between using the active 116 or passive cooling 106 modes or systems. The controller can communicate with the components of the cooling system via control signal lines 129.

The battery system 102 can include a plurality of electric batteries. The battery system 102 is operatively coupled to a powertrain 110 of the electric machine through an electrical line 128 to power one or more components of the machine. The battery can also be coupled to valve 122 and to one or more check valves 124 located in cooling system lines 126.

Each of the batteries in the battery system 102 can include sensors and other control devices to send to the controller 100 certain information regarding the state of the battery. For example, some information regarding the battery state can include the state of charge, the current, the depth of discharge, the battery temperature, the state of health, and the EFC (equivalent full cycles) of each battery.

The cooling system 104 can include two different operational modes, a passive cooling radiator system 106 and an active cooling system 116, such as a chiller. The radiator system 106 cools the battery system 102 by using ambient outside air passing through the radiator 106 filled with a coolant, to deliver cooler air via a fan 120.

The active cooling system 116 can generally include a condenser 112, expansion valve 114, an evaporator 116, and a compressor 118 coupled through cooling systems lines 126 to provide an active chiller device to cool the battery system 102.

As noted, in battery electric machines applications, the battery lifecycle is defined by cyclic aging of the battery. The key factors in battery cyclic degradation are state of charge, depth of discharge, current, and battery temperature. In an electric machine environment, the current is largely determined by the application needs and battery size, and the state of charge is generally optimized based on the depth of discharge for a particular application as to avoid unnecessary downtime for charging. This leaves temperature, which the machine does have a control over, but can be very costly in terms of weight, monetary (lifecycle cost), and power (efficiency, battery throughput life), as well as facing diminishing returns.

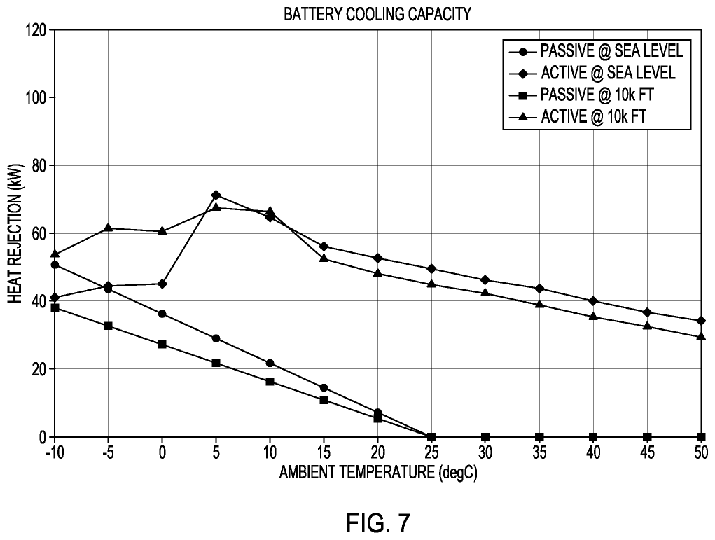

Therefore, it is important for the machine to use the battery cooling wisely, as to optimize the benefit for the given cost. The variables that can go into a cost-benefit analysis of cooling are shown in FIGS. 7-10.

FIG. 7 shows a graph of battery cooling capacity, in accordance with this disclosure. Here is shown the relative difference between the active and passive cooling at different ambient temperatures. The cooling capacity of the passive system grows linearly with temperature gradient (the difference between coolant temperature and ambient temperature), and a large cooling capacity is possible at cooler ambient conditions, whereas the active system flatlines at lower temperatures eventually derating as chiller systems have operating limitations at cooler temperatures. Conversely the passive system does not work well where ambient is near or above desired battery temperature, which is relatively cool.

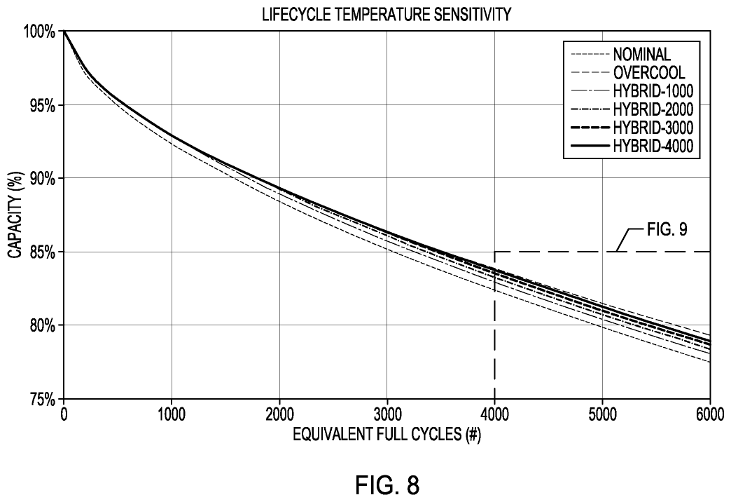

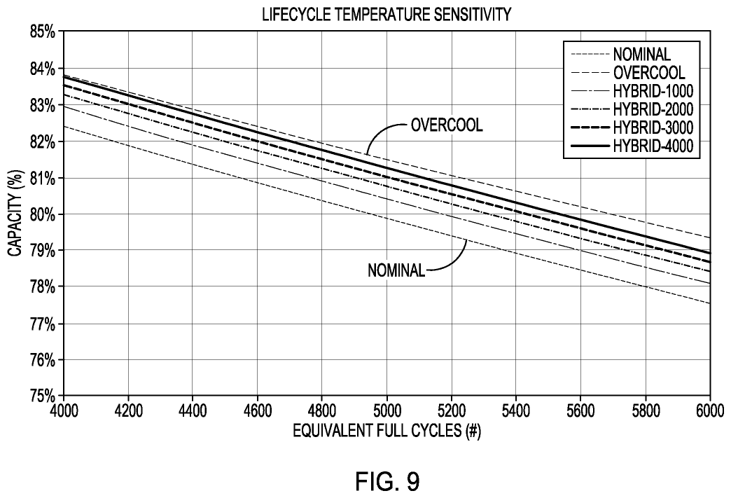

FIG. 8 shows a graph depicting lifecycle temperature sensitivity, in accordance with this disclosure, and FIG. 9 shows a blown-up portion of the graph of FIG. 8.

These graphs show the shape of the degradation curve—exponential decay—such that overcooling early in the lifecycle has more value than overcooling later in the lifecycle, for the same cost, due to the rate of degradation being higher earlier in the battery lifecycle.

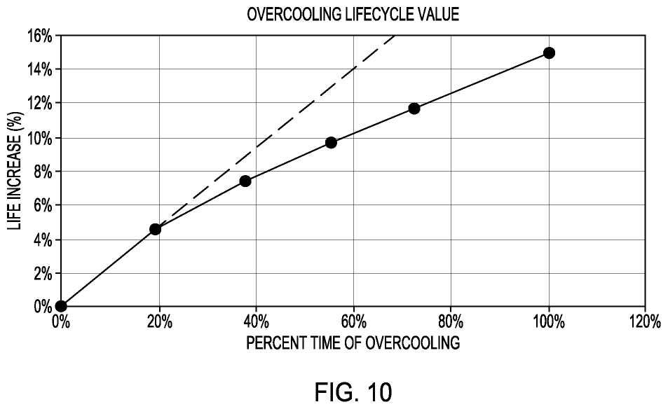

FIG. 10 shows a graph depicting overcooling lifecycle value, in accordance with this disclosure. Here, it is shown that overcooling increases the life of the battery, but the slope of the graph flattens such that each amount of increased overcooling adds less percentage of life. Thus, there can be a point where the cost of overcooling can be more than the value of increasing the battery life.

Accordingly, a cooling control strategy is discussed herein that can overcool, and potentially use passive cooling or the active cooling, when at earlier stages of battery life, but then not use that strategy at later stages. The cooling can be dynamically controlled based on battery state of health—which can be determined by a number of methods, for example, by monitoring number of cycles, throughput, or charge vs. voltage of the battery. If a system has active and passive cooling, then the strategy will involve controlling the two methods of cooling in conjunction with condition of the battery and the operating environment.

Accordingly, the controller 100 is configured to dynamically adjust a battery cooling system temperature set point or cooling demand based on a condition of the battery system 102 and an application environment, such as the ambient conditions 130. In general, there are three scenarios where there can be outsized value for applying more cooling: passive opportunistic overcooling in cool ambient temperatures, battery lifecycle based cooling, and degradation rate based decisions.

### Opportunistic Overcooling

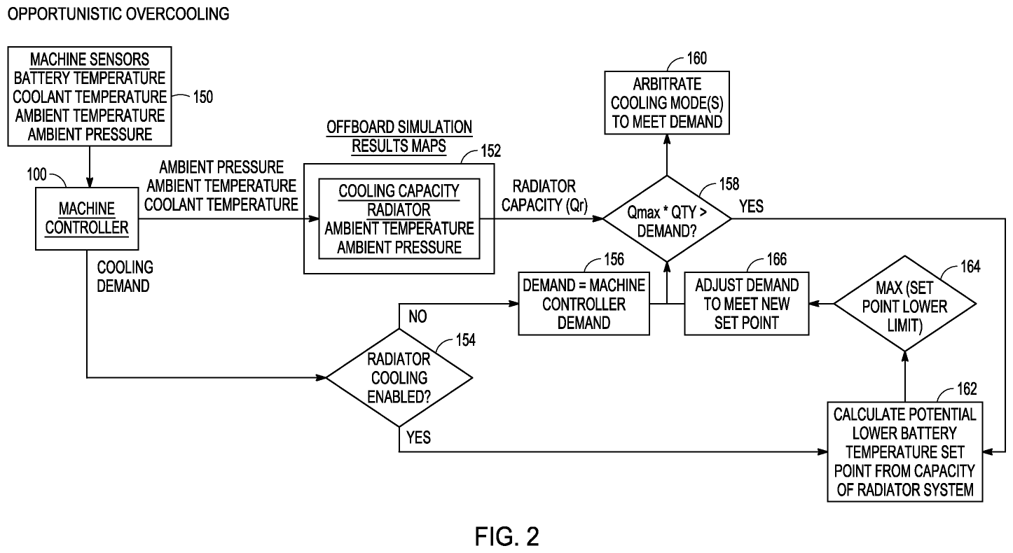

For example, FIG. 2 shows a schematic view of the control system for opportunistic overcooling using the passive cooling system 104, in accordance with one example.

Here, the controller 100 receives input information 150 regarding the application environment including the battery temperature, the coolant temperature, the ambient temperature, and the ambient pressure. The controller can determine the cooling capacity of the cooling system at block 152 based on the ambient pressure, the ambient pressure, and the coolant temperature by using offboard simulation results stored in the controller. In some examples, the system can further include factors for self-calibrating over time by looking at expected vs observed heat transfer from the cooler.

The controller determines at block 154 if passive cooling is enabled, if not then the cooling demand at block 156 is equal to the demand determined by the machine controller 100 which is based on a coolant temperature set point determined by the present battery temperature.

At block 158, if the cooling demand is less than the radiator cooling capacity, then the control system moves to block 162 to estimate a potential battery temperature if the full cooling system capacity is used. At block 164, the controller is configured to set a temperature set point request to a maximum of a battery low temperature limit and an estimated potential battery temperature, and the controller at block 166, adjusts the battery cooling temperature set point lower to utilize up to the full cooling system capacity.

At block 158, if the cooling demand is more than the radiator capacity, then the control system moves to block 160 to arbitrate the cooling mode to meet the demand. For example, the system can speed up the fan, change to cooling mode, or adjust the set point to a higher temperature, for example.

This control setup allows for passive radiator opportunistic overcooling when the ambient temperature is relatively low and/or the application load factor is low. This is advantageous since the overcooling in cool ambient temperature with a passive radiator cooling mode is relatively inexpensive compared to the active cooling refrigeration circuit chiller alternative. As noted for FIG. 7, since the capacity of the passive system grows linearly with temperature gradient, a large capacity is possible at cooler ambient conditions with negligible parasitic power cost penalty. Conversely the passive system does not work well where ambient is near or above desired battery temperature, which is relatively cool. Additionally, the active system has limitations on lower temperature operation, both ambient and coolant.

### Lifecycle Overcooling

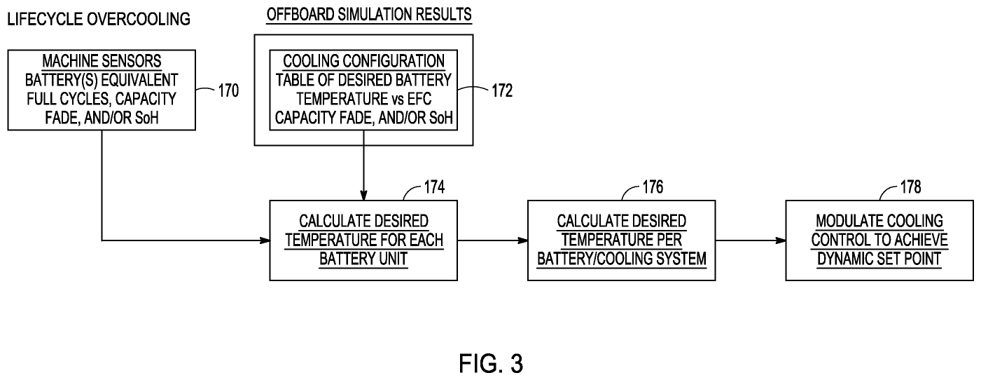

FIG. 3 is a schematic view of a control system for lifecycle overcooling, in accordance with one example. The battery lifecycle based cooling value comes from the shape of the degradation curve—exponential decay—such that overcooling early in the lifecycle has more value than overcooling later in the lifecycle, for the same cost.

Here, the controller can receive information at block 170 from the batteries or other machine sensors regarding the battery equivalent full cycles (EFC), or capacity fade, and/or state of health (SoH) from each battery of the battery system. A cooling configuration at block 172 uses offboard simulation results that are used to determine an optimal battery cooling temperature vs an EFC, or capacity fade, and/or SoH based temperature schedule. Based on the information from blocks 170 and 172, the controller can determine at blocks 174 and 176 the battery cooling system set point based on the EFC, or capacity fade, and/or SoH based temperature schedule for each battery in battery system, and then for the entire battery system. At block 178, the system is configured to dynamically adjust the cooling system (either passive cooling or active cooling) to achieve a dynamic battery cooling system temperature set point.

### Degradation Rate Control

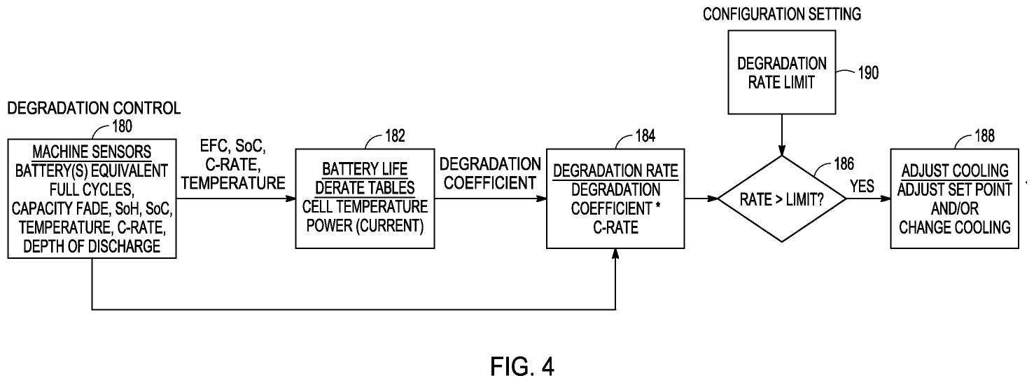

FIG. 4 is a schematic view of a control system for cooling based on degradation, in accordance with one example.

The degradation rate based cooling determinations stem from the fact that the battery cyclic degradation is not linear, such that 1 degree change in temperature at 25 C may be worth less than 1 degree change at 45 C. (See FIG. 10). Additionally, degradation is proportional to throughput, such that the degradation factors may be bad (temperature, SoC), but the net degradation impact (SoH) is minimal since the throughput (c-rate) is low.

Here, the controller includes a battery degradation rate limit at block 190. The degradation rate limit can be set and configured by a user, for example. In some examples, the degradation rate limit can be set by the owner or it can be dynamically adjusted via remote means from a fleet management system. The parameter may not be a singular constant, but a table based on EFC/SoH, and may also change based on operating mode (charge/discharge), and the adjustable parameter may be applied to the curve as an adjustment. The control system then can be configured to determine an actual degradation rate of the battery system, and if the actual degradation rate is greater than the battery degradation rate limit, the controller is configured to adjusting a cooling set point to correct.

For example, at block 180, the system can collect machine information such as the battery EFC, or capacity fade, and/or SoH, the state of charge (SoC), the battery temperature, the depth of discharge, and the c-rate, where the c-rate is the ratio of current to charge capacity of the battery. At block 182, battery degradation tables can determine degradation based the battery temperature and the power (current, c-rate, and depth of discharge), then at block 184 the effective battery degradation rate by multiplying a degradation coefficient by the c-rate. At block 186, this effective degradation rate is compared to the degradation rate limit set in block 190. If the effective rate is greater than the limit, then at block 188, the system adjusts the temperature cooling set point to reduce degradation, which may change the cooling mode.

### TCO Degradation Control

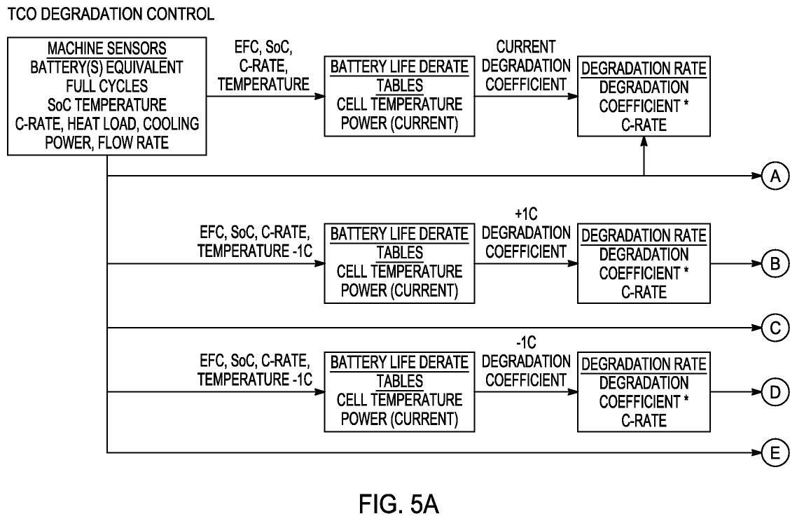

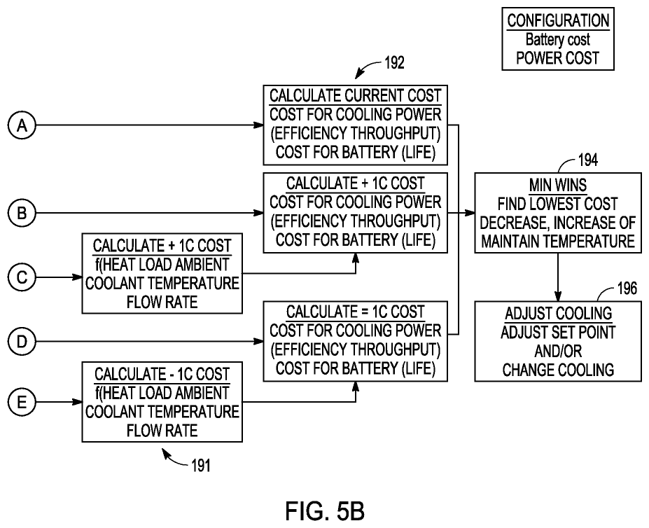

FIGS. 5A and 5B show a schematic view of a control system for cooling based on total cost of ownership (TCO) degradation, in accordance with one example.

TCO degradation control uses the same basic control system as degradation control of FIG. 4, but here, the power costs are determined in blocks 191 and the total cost is determined at blocks 192. The control system can determine the current cost, thus the system can include a configuration of battery cost (per unit of throughput or State of Health/Capacity Fade) and cooling cost (per unit of power, including secondary effects). Then the controller is configured to calculate current degradation factors based on a state of charge, a current, depth of discharge, and a battery temperature, and to calculate potential degradation factors at battery temperature set points above and below the present battery temperature set point and calculate degradation rates by multiplying coefficients by the c-rate, which can be the current/rated charge capacity of the battery. Here, the controller calculates an estimated cooling power required for potential new set points at +1 C and −1 C, for example. In block 194, the control system calculates a plurality of costs based on cooling power and battery degradation rate, and the controller adjusts cooling in block 196 based on a lowest cost solution.

### Combined Cooling System

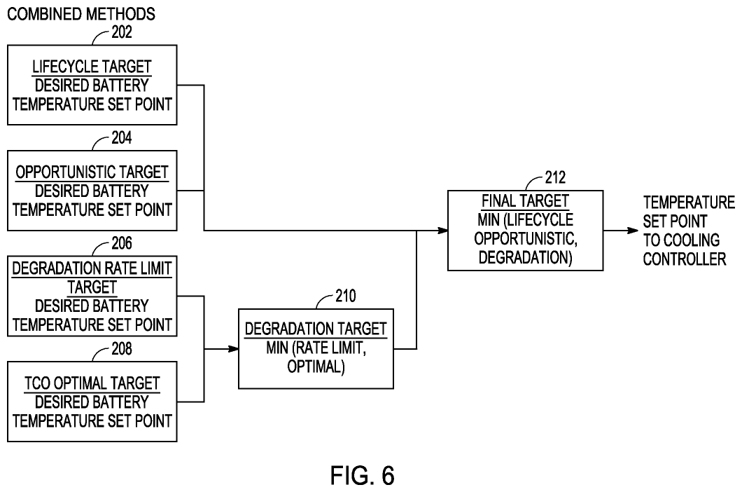

FIG. 6 is a schematic view of a combined cooling control system, in accordance with one example. Here, one or more of the control systems and methods of FIGS. 2-5A, 5B can be combined to determine the most optimal cooling solution based on cooling cost vs cooling value estimations. The control concept looks at either cooling opportunity or uses degradation rate as an influencing factor in cooling usage. It is noted that not all the cooling control systems have to be active. For instance, only opportunistic target may be enabled through machine configuration with others disabled.

Accordingly, the combined system finds target temperature set points for each of the cooling methods discussed above at blocks 202, 204, 206, and 208, the degradation rate limit of block 206 and the TCO optimal target are compared and the degradation target temperature set point is determined at block 210 based on the minimum of the two targets of blocks 206 and 208. Then the system, in block 212, determines the final temperature set point target by looking at the minimum set point from the lifecycle target set point, the opportunistic target set point and the degradation target set point, from blocks 202, 204, and 210, respectively.

The combined cooling system of FIG. 6 provides a system wherein the controller is configured to dynamically adjust a battery cooling set point based on a minimum temperature set point of a battery lifecycle temperature set point, an opportunistic temperature set point, and a degradation target temperature set point.

As discussed above, the battery lifecycle temperature set point can be determined by the controller determining a battery lifecycle state by obtaining an equivalent full cycle (EFC), or capacity fade, and/or SoH information from each battery of the battery system, and wherein the controller includes offboard simulation results that are used to determine an optimal battery cooling temperature vs an EFC, or capacity fade, and/or SoH based temperature schedule, and wherein the controller is configured to determine the battery lifecycle temperature set point based on the EFC, or capacity fade, and/or SoH based temperature schedule for each battery in battery system.

The opportunistic temperature set point can be determined by the controller receiving information regarding an ambient temperature and machine conditions and the controller is configured to determine a cooling capacity of the cooling system based on the ambient temperature, an ambient pressure, and a temperature of a coolant in the cooling system, wherein the controller is configured to estimate if a demand for cooling by the battery system is less than the cooling capacity and to estimate a potential battery temperature if the full cooling system capacity is used, and wherein the controller is configured to set a temperature request set point to a maximum of a battery low temperature limit and an estimated potential battery temperature, and the controller determines the opportunistic temperature set point to utilize up to the full cooling system capacity.

Referring again to FIGS. 1-3, in one embodiment, a system for cooling a battery of an electric machine can include the cooling system 104 coupled to the controller 100 and configured to cool the battery system 102, wherein the cooling system 104 includes an active cooling system 116 and a passive cooling system including a radiator 106. The controller 100 can be configured to use the passive cooling system 106 when it is advantageous to do so, such as lower ambient temperatures or low cooling demand, and to use the active system 116 based on a condition of the battery system and an application environment.

For example, the passive cooling system can include a passive radiator cooling system and the controller 100 can be configured to estimate if a demand for cooling by the battery system is less than a cooling capacity of the passive radiator cooling system based on the application environment including an ambient temperature, and the controller can estimate a potential battery temperature if the full passive cooling system capacity is used. The controller can then set a temperature request set point to a maximum of a battery low temperature limit and an estimated potential battery temperature, and the controller adjusts the battery cooling control set point lower to utilize up to the full cooling system capacity.

The controller determines the condition of the battery system by determining a battery lifecycle state by obtaining an equivalent full cycle (EFC), or capacity fade, and/or SoH information from each battery of the battery system, and the controller includes offboard simulation results that are used to determine an optimal battery cooling temperature vs an EFC, or capacity fade, and/or SoH based temperature schedule. The controller is configured to determine the battery cooling system set point based on the EFC, or capacity fade, and/or SoH based temperature schedule for each battery in battery system.

### INDUSTRIAL APPLICABILITY

The present system is applicable to many industrial battery vehicles including, but not limited to, continuous miners, feeder breakers, roof bolters, utility vehicles for mining, underground mining loaders, underground articulated trucks, or any other vehicle used for industrial purposes, such as hauling, excavating, drilling, loading, dumping, compacting, etc., including but not limited to work machines such as an excavator, a front-end loader, a dozer, a haul truck, locomotive, or other types of work machines. Further, the techniques of this disclosure, while especially suited to use in battery-powered vehicles, also could be used in hybrid-powered vehicles, fuel-cell vehicles, and internal-combustion-powered vehicles.

Utilizing the cooling system and modes discussed above, and referring to FIG. 2, one method of controlling a cooling system can include determining the cooling system capacity based on ambient temperature, ambient pressure and the coolant temperature; determining if the cooling mode is a passive cooling radiator; determining if cooling demand is less that the cooling capacity; estimating potential battery temperature if the full cooling capacity is used; setting the temperature set point request to maximum of a battery low temperature limit and an estimated potential temperature; and adjusting the cooling control temperature set point lower to utilize up to full capacity, as limited by the battery lower temperature limit.

Referring to FIG. 3, one method of controlling a cooling system can include determining a battery lifecycle state by obtaining EFC (equivalent full cycle), or capacity fade, and/or SoH information from each battery; using offboard simulation results used to determine optimal battery cooling temperature vs a EFC, or capacity fade, and/or SoH schedule; determining the cooling system set point based on the EFC, or capacity fade, and/or SoH based temperature schedule for each battery in the battery system; and arbitrating the cooling system to achieve a dynamic set point.

Referring to FIG. 4, one method of controlling a cooling system can include providing a degradation rate limit; calculating current degradation factors based on state of charge, current, depth of discharge, and battery temperature; calculating degradation rate by multiplying coefficient by current (c-rate); and comparing the calculated rate to the degradation rate limit, and if above, then adjusting the cooling set point to correct.

Referring to FIGS. 5A and 5B, one method of controlling a cooling system can include providing a configuration of battery cost (per unit of throughput or degradation) and cooling cost (per unit of power, including secondary effects); calculating current degradation factors based on state of charge, current, depth of discharge, and battery temperature; calculating potential degradation factors at temperature set points above and below current temperature; calculating degradation rates by multiplying coefficients by current (c-rate); calculating estimated cooling power required for the calculated temperature set points; calculating costs based cooling power and battery degradation rate; and adjusting cooling based on lowest cost solution.

In summary, the proposed system uses the concept of controlling cooling based on the dynamic state of health of battery/age of battery. The system uses a controller that connects with a battery system and a cooling system having at least two modes to use cooling wisely.

The controller includes the configuration of the battery cost and the cooling cost, by calculating the current degradation factors of the battery based on state of charge, current, depth of discharge, and temperature. The degradation rates are calculated by multiplying coefficients to the current.

The battery lifecycle-based cooling involves using the cooling system more (i.e., early cooling) to manage battery temperature throughout its life. This early cooling has a more significant impact on battery health than late cooling. It includes determining battery lifecycle state by obtaining equivalent full cycle (EFC), or capacity fade, and/or SoH information from each battery. Based on the EFC, or capacity fade, and/or SoH temperature schedule for each battery, determining cooling system set point and adjusting cooling system to achieve dynamic set point. Passive overcooling involves a passive radiator-based cooling system which uses water cooling and is more energy efficient. It includes determining cooling system capacity based on ambient temperature, pressure and coolant temperature. It further checks if the demand is less than the capacity and estimates the potential battery temperature for limiting temperature request based on the output to fine-tune the cooling system to make sure it is running efficiently.

The above detailed description is intended to be illustrative, and not restrictive. The scope of the disclosure should, therefore, be determined with references to the appended claims, along with the full scope of equivalents to which such claims are entitled.

What is claimed is:

1. A system for cooling a battery of an electric machine, the system comprising:
a controller;
a battery system coupled to the controller; and
a cooling system coupled to the controller and configured to cool the battery system;
wherein, the controller is configured to dynamically adjust a battery cooling system temperature set point or cooling demand based on a condition of the battery system and an application environment.

2. The system of claim 1, wherein the controller receives information regarding the application environment including an ambient temperature and an ambient pressure.

3. The system of claim 2, wherein the controller is configured to determine a cooling capacity of the cooling system based on the ambient temperature, the ambient pressure, and a temperature of a coolant in the cooling system.

4. The system of claim 3, wherein the cooling system includes a passive radiator cooling system and the controller is configured to estimate if a demand for cooling by the battery system is less than the cooling capacity and to estimate a potential battery temperature if the full cooling system capacity is used.

5. The system of claim 4, wherein the controller is configured to set a temperature request set point to a maximum of a battery low temperature limit and an estimated potential battery temperature, and the controller adjusts the battery cooling control set point lower to utilize up to the full cooling system capacity.

6. The system of claim 1, wherein the controller is configured to determine the condition of the battery system by determining a battery lifecycle state by obtaining an equivalent full cycle (EFC), or capacity fade, and/or SoH information from each battery of the battery system.

7. The system of claim 6, wherein the controller includes offboard simulation results that are used to determine an optimal battery cooling temperature vs an EFC, or capacity fade, and/or SoH based temperature schedule, and wherein the controller is configured to determine the battery cooling system set point based on the EFC, or capacity fade, and/or SoH based temperature schedule for each battery in battery system.

8. The system of claim 7, wherein the controller is configured to adjust the cooling system to achieve a dynamic battery cooling system set point.

9. The system of claim 1, wherein the controller includes a battery degradation rate limit which is configurable by an operator or dynamically adjusted by a remote fleet management system, and the controller is configured to determine an effective degradation rate of the battery system, and if the effective degradation rate is greater than the battery degradation rate limit, the controller is configured to adjusting a cooling set point to correct.

10. The system of claim 9, wherein the effective battery degradation rate is determined by the controller by calculating current degradation factors of the battery system based on a state of charge, a current, depth of discharge, and a battery temperature, and to determine the effective battery degradation rate by multiplying a degradation coefficient by a c-rate.

11. The system of claim 1, wherein the controller includes a configuration of battery cost, per unit of throughput or degradation, and cooling cost, per unit of power, including secondary effects, wherein the controller is configured to calculate current degradation factors based on a state of charge, a current, depth of discharge, and a battery temperature, and to calculate potential degradation factors at different battery temperature set points above and below the battery temperature, and calculate degradation rates by multiplying coefficients by a c-rate.

12. The system of claim 11, wherein the controller calculates an estimated cooling power required for the different battery temperature set points and calculates a plurality of different costs based on cooling power and battery degradation rate, and the controller adjusts cooling based on a lowest cost solution.

13. A system for cooling a battery of an electric machine, the system comprising:
a controller;
a battery system coupled to the controller; and
a cooling system coupled to the controller and configured to cool the battery system;
wherein the controller is configured to dynamically adjust a battery cooling set point based on a minimum temperature set point of one of a battery lifecycle temperature set point, an opportunistic temperature set point, and a degradation target temperature set point.

14. The system of claim 13, wherein the degradation target temperature set point is based on a minimum temperature set point of a degradation rate limit temperature set point and a total cost ownership (TCO) temperature set point.

15. The system of claim 13, wherein the battery lifecycle temperature set point is determined by the controller determining a battery lifecycle state by obtaining an equivalent full cycle (EFC), or capacity fade, and/or SoH information from each battery of the battery system, and wherein the controller includes offboard simulation results that are used to determine an optimal battery cooling temperature vs an EFC, or capacity fade, and/or SoH based temperature schedule, and wherein the controller is configured to determine the battery lifecycle temperature set point based on the EFC, or capacity fade, and/or SoH based temperature schedule for each battery in battery system.

16. The system of claim 13, wherein the cooling system includes a passive radiator cooling system and the opportunistic temperature set point is determined by the controller receiving information regarding an ambient temperature and machine conditions and the controller is configured to determine a cooling capacity of the cooling system based on the ambient temperature, an ambient pressure, and a temperature of a coolant in the cooling system, wherein the controller is configured to estimate if a demand for cooling by the battery system is less than the cooling capacity and to estimate a potential battery temperature if the full cooling system capacity is used, and wherein the controller is configured to set a temperature request set point to a maximum of a battery low temperature limit and an estimated potential battery temperature, and the controller determines the opportunistic temperature set point to utilize up to the full cooling system capacity.

17. A system for cooling a battery of an electric machine, the system comprising:
a controller;
a battery system coupled to the controller; and
a cooling system coupled to the controller and configured to cool the battery system, wherein the cooling system includes an active cooling system and a passive cooling system;
wherein the controller is configured to use the passive cooling system when a cooling demand is below a passive cooling capacity due to cold ambient conditions and/or low application load factor, and to use the active system when the cooling demand is greater than the passive cooling capacity and the active cooling capacity is greater than the passive cooling capacity.

18. The system of claim 17, wherein the passive cooling system includes a passive radiator cooling system and the controller is configured to estimate if a demand for cooling by the battery system is less than a cooling capacity of the passive radiator cooling system based on the application environment including an ambient temperature, pressure, and coolant temperature, and to estimate a potential battery temperature if the full cooling system capacity is used, and wherein the controller is configured to set a temperature request set point to a maximum of a battery low temperature limit and an estimated potential battery temperature, and the controller adjusts a battery cooling control set point lower to utilize up to the full cooling system capacity.

19. The system of claim 17, wherein the controller determines the condition of the battery system by determining a battery lifecycle state by obtaining an equivalent full cycle (EFC), or capacity fade, and/or SoH information from each battery of the battery system, and the controller includes offboard simulation results that are used to determine an optimal battery cooling temperature vs an EFC, or capacity fade, and/or SoH based temperature schedule, and wherein the controller is configured to determine a battery cooling system set point based on the EFC, or capacity fade, and/or SoH based temperature schedule for each battery in battery system.

20. The system of claim 19, wherein the controller is configured to adjust the cooling system to achieve a dynamic battery cooling system set point.
